(19) United States
(12) Patent Application Publication
(10) Pub. No.: US 2006/0199384 A1
(43) Pub. Date: Sep. 7, 2006

(54) Method of forming thin film, and method of manufacturing semiconductor device

(76) Inventors: Takashi Ando, Tokyo (JP); Tomoyuki Hirano, Kanagawa (JP)

Correspondence Address: SONNENSCHEIN NATH & ROSENTHAL LLP, P.O. BOX 061080, WACKER DRIVE STATION, SEARS TOWER, CHICAGO, IL, 60606-1080, US

(21) Appl. No.: 11/365,052

(22) Filed: Mar. 1, 2006

(30) Foreign Application Priority Data
Mar. 3, 2005 (JP) P2005-058401
Dec. 20, 2005 (JP) P2005-366430

(51) Int. Cl. H01L 21/44

(52) U.S. Cl. 438/680

(57) ABSTRACT

A method of forming a thin film by use of an ALD process, including: a first step of supplying a raw material gas containing an Hf atom and an Si atom into a treatment atmosphere and adsorbing a raw material gas component onto a surface to be treated of a substrate so as to form a layer containing Hf atoms and Si atoms; a second step of purging by an inert gas; a third step of supplying an oxidizing gas into the treatment atmosphere and permitting the oxidizing gas to react with the raw material gas component adsorbed on the surface to be treated of the substrate so as to form a layer of O atoms; and a fourth step of purging by an inert gas, the film forming cycle of the first to fourth steps being repeated. In the thin film forming method and a semiconductor device manufacturing method, an impurity removing step composed of a fifth step of supplying an oxygen-containing gas into the treatment atmosphere so as to oxidize impurities in the thin film and a sixth step of purging by an inert gas is provided between the fourth step and the first step of the film forming cycle.

### CROSS REFERENCES TO RELATED APPLICATIONS

The present invention contains subject matter related to Japanese Patent Application JP 2005-058401 filed in the Japanese Patent Office on Mar. 3, 2005 and Japanese Patent Application JP 2005-366430 filed in the Japanese Patent Office on Dec. 20, 2005, the entire contents of which being incorporated herein by reference.

### BACKGROUND OF THE INVENTION

The present invention relates to a method of forming a thin film and a method of manufacturing a semiconductor device, particularly to a method of forming a thin film and a method of manufacturing a semiconductor device wherein an insulation film composed of a high-k material is formed by an atomic layer deposition (ALD) process.

Attendant on miniaturization of devices, development of a high-k material as a material for a gate insulation film and a capacitor insulation film has been under way. An insulation film composed of a high-k material is high in dielectric constant; therefore, in the case where this insulation film is used, for example, as a gate insulation film, the same gate capacitance as in the case of using silicon oxide (SiO₂) can be obtained even when the film thickness is increased to a several times that in the case of using SiO₂.

As a method of forming a film of such a high-k material, an example in which the ALD process is used has been reported (see, for example, Japanese Patent Laid-Open No. 2003-318174). When a high-k material film is formed by the ALD process, a highly sophisticated control of the thickness and composition of the insulation film can be achieved, but, since it is a low-temperature process, it is difficult to form a dense film with little impurities. It has been known that the impurities in the high-k material film lead to generation of a leakage current through the trap level, and it is therefore important to reduce the concentration of the impurities (C, H, Cl or the like) arising from the raw material gas.

Accordingly, in order to remove the impurities in the film, an example has been reported in which each time when a thin film having a thickness of not more than about 2 nm is formed on the surface to be treated of a substrate, the substrate is taken out of the treatment chamber, is introduced into another chamber, and is subjected to an annealing treatment using ammonia (NH₃) gas.

### SUMMARY OF THE INVENTION

However, where the annealing treatment is conducted in another chamber by the just-mentioned method, throughput is spoiled conspicuously. Therefore, it is difficult to apply such a method to mass production. In addition, since NH₃ gas is used as the atmosphere gas in carrying out the annealing treatment, in the case where a metal silicate film or a metal oxide film is formed as the high-k material film, oxygen atoms would be replaced by nitrogen atoms through the treatment with NH₃ gas. Therefore, in the case of forming a metal silicate film or a metal oxide film, it is unfavorable to conduct the impurity removing step using NH₃ gas.

Thus, there is a need to carry out a step of removing impurities from a thin film formed by a thin film forming method using an ALD process, by using the same treatment chamber as used in the film forming step, and to form a metal silicate film and a metal oxide film which are reduced in the concentration of the impurities remaining in the film.

According to an embodiment of the present invention, there is provided a first method of forming a thin film by an ALD process; in which the following steps are sequentially carried out. First, in a first step, a raw material gas containing at least either of metallic atoms and silicon atoms is supplied into a treatment atmosphere, and a raw material gas component is adsorbed on a surface to be treated of a substrate, so as to form a layer containing at least either of the metallic atoms and silicon atoms. Next, in a second step, an inert gas is supplied into the treatment atmosphere so as to purge the raw material gas present in the treatment atmosphere. Subsequently, in a third step, an oxidizing gas is supplied into the treatment atmosphere, and is permitted to react with the raw material gas component adsorbed on the surface to be treated of the substrate, so as to form a layer of oxygen atoms. Thereafter, in a fourth step, an inert gas is supplied into the treatment atmosphere so as to purge the oxidizing gas present in the treatment atmosphere. The film forming cycle composed of the first to fourth steps is repeated, to form a thin film on the surface to be treated. Besides, between the fourth step and the first step, an impurity removing step is conducted which includes a fifth step of supplying an oxygen-containing gas into the treatment atmosphere so as to oxidize impurities in the thin film and a sixth step of supplying an inert gas into the treatment atmosphere so as to purge the oxygen-containing gas and the oxidized impurities present in the treatment atmosphere.

According to another embodiment of the present invention, there is provided a method of manufacturing a semiconductor device including a capacitor having a capacitor insulation film sandwiched between electrodes, in which the first method of forming a thin film is applied to the formation of the capacitor insulation film. According to a further embodiment of the present invention, there is provided a method of manufacturing a semiconductor device having a gate electrode provided on the upper side of a substrate, with a gate insulation film therebetween, in which the first method of forming a thin film is applied to the formation of the gate insulation film.

According to the first method of forming a thin film and the methods of manufacturing a semiconductor device as above, an oxygen-containing gas is supplied in the fifth step into the same treatment atmosphere as in the film forming cycle. As a result of this, the impurities composed of carbon (C) and hydrogen (H) arising from the raw material gas in the treatment atmosphere are oxidized, to be carbon dioxide (CO₂) and water (H₂O). Thereafter, the oxidized impurities are purged together with the oxygen-containing gas in the sixth step. This makes it possible to conduct the impurity removing treatment in the same treatment chamber as that used for the film forming cycle.

In addition, since the impurity removing treatment is conducted by use of the oxygen-containing gas, a more favorable situation is obtained as compared with the case of using NH₃ gas in that, in forming a metal silicate film or a metal oxide film, oxygen atoms would not be replaced by nitrogen atoms during the film formation, and a metal silicate film and a metal oxide film deprived of impurities can be formed. This makes it possible to suppress the leakage current arising from the impurities present in the film through the trap level.

According to yet another embodiment of the present invention, there is provided a second method of forming a thin film by use of an ALD process, in which the following steps are sequentially carried out. First, in a first step, a raw material gas containing either of metallic atoms and silicon atoms is supplied into a treatment atmosphere, and a raw material gas component is adsorbed onto a surface to be treated of a substrate, so as to form a layer containing at least either of the metallic atoms and the silicon atoms. Next, in a second step, an inert gas is supplied into the treatment atmosphere so as to purge the raw material gas present in the treatment atmosphere. Subsequently, in a third step, under the condition where at least one of the pressure or the treatment atmosphere and the temperature of the substrate is higher than that in the first step, an oxidizing gas is supplied into the treatment atmosphere, and is permitted to react with the raw material gas component adsorbed on the surface to be treated of the substrate, so as to form a layer of oxygen atoms and to oxidize impurities. Thereafter, in a fourth step, an inert gas is supplied into the treatment atmosphere so as to purge the oxidized impurities together with the oxidizing gas present in the treatment atmosphere. The film forming cycle composed of the first to fourth steps is repeated, so as to form the thin film.

According to a yet further embodiment of the present invention, there is provided a method of manufacturing a semiconductor device including a capacitor having a capacitor insulation film sandwiched between electrodes, in which the second method of forming a thin film is applied to the formation of the capacitor insulation film. According to still another embodiment of the present invention, there is provided a method of manufacturing a semiconductor device having a gate electrode provided on the upper side of a substrate, with a gate insulation film therebetween, in which the second method of forming a thin film is applied to the formation of the gate insulation film.

According to the second method of forming a thin film and the methods of manufacturing a semiconductor device as above, in the third step, an oxidizing gas is supplied into the treatment atmosphere under the condition where at least one of the pressure of the treatment atmosphere and the temperature of the substrate is higher than that in the first step, whereby a layer of O atoms is formed, and the impurities C and H arising from the raw material gas are oxidized to be CO₂ and H₂O. Thereafter, the oxidized impurities are purged together with the oxidizing gas in the fourth step. This makes it possible to conduct the impurity removing treatment during the film forming cycle.

In addition, since the impurity removing treatment is conducted by use of the oxygen-containing gas, a more favorable situation is obtained as compared with the case of using NH₃ gas in that, in forming a metal silicate film or a metal oxide film, oxygen atoms would not be replaced by nitrogen atoms during the film formation, and a metal silicate film and a metal oxide film deprived of impurities can be formed. This makes it possible to suppress the leakage current arising from the impurities present in the film through the trap level.

As has been described above, according to the method of forming a thin film and the method of manufacturing a semiconductor device of the present invention, the impurity removing treatment can be conducted in the same treatment chamber as that used for the film forming cycle and during the film forming cycle, so that throughput can be enhanced as compared with the case where the impurity removing treatment is conducted in another chamber. Besides, leakage current is suppressed and, therefore, the yield of the device being manufactured can be enhanced.

### BRIEF DESCRIPTION OF THE DRAWINGS

FIG. 1 is a configuration diagram of an ALD apparatus used for an embodiment of the method of forming a thin film according to the present invention;

FIG. 2 is a sectional diagram (No. 1) for illustrating a first embodiment of the method of forming a thin film and the method of manufacturing a semiconductor device according to the present invention;

FIG. 3 is a flowchart for illustrating the first embodiment of the method of forming a thin film and the method of manufacturing a semiconductor device according to the present invention;

FIG. 4 is a graph showing the variation with time of the pressure of the treatment atmosphere in the first embodiment of the method of forming a thin film and the method of manufacturing a semiconductor device according to the present invention;

FIG. 5 is a sectional diagram (No. 2) for illustrating the first embodiment of the method of forming a thin film and the method of manufacturing a semiconductor device according to the present invention;

FIGS. 6A and 6B are manufacturing step sectional diagrams for illustrating a second embodiment of the method of forming a thin film and the method of manufacturing a semiconductor device according to the present invention;

FIG. 7 is a flowchart for illustrating a third embodiment of the method of forming a thin film and the method of manufacturing a semiconductor device according to the present invention;

FIG. 8 is a graph showing the variation with time of the pressure of the treatment atmosphere in the third embodiment of the method of forming a thin film and the method of manufacturing a semiconductor device according to the present invention;

FIG. 9 is a graph showing the concentration of an impurity in a thin film, for Examples 1 and 2 of the method of forming a thin film according to the present invention and Comparative Example 1;

FIG. 10 is a graph showing the trench capacitor capacitance and leakage current, for Examples 1 and 2 of the method of forming a thin film according to the present invention and Comparative Examples 1 and 2;

FIG. 11 is a graph showing the relationship between electrical film thickness and leakage current, for Comparative Examples 1 and 3 to 6; and

FIGS. 12A and 12B are sectional TEM photographs of nMOSFETs in Examples 3 and Comparative Example 7.

### DETAILED DESCRIPTION OF THE PREFERRED EMBODIMENTS

Now, examples of embodiments of the method of forming a thin film by use of an ALD process according to the present invention will be described in detail below.

### First Embodiment

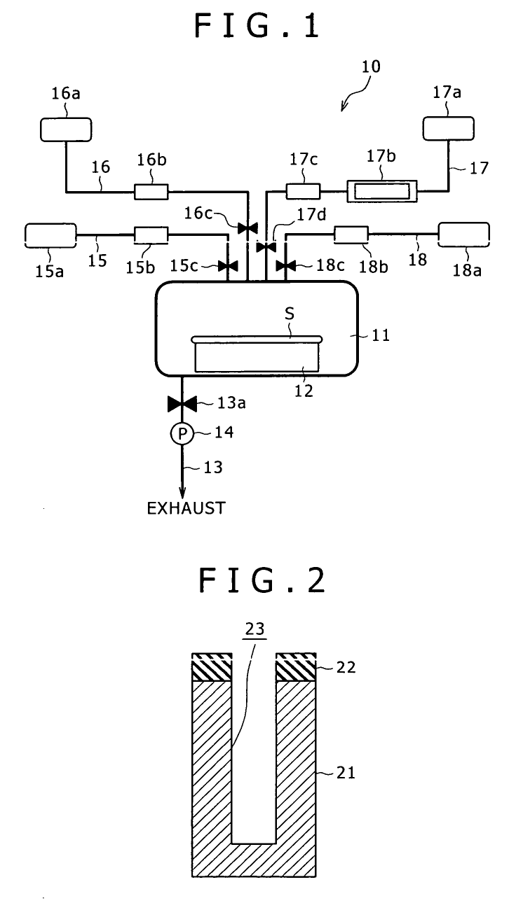

In this embodiment, in the method of manufacturing a semiconductor device using the first method of forming a thin film according to the present invention, an example of forming a capacitor insulation film of a deep trench type trench capacitor according to an ALD process will be described. As the capacitor insulation film, a film of hafnium silicate (HfSiOₓ) which is a high-k material is formed. Here, in describing the method of forming the hafnium silicate film by the ALD process, the ALD apparatus used for the film formation will be described referring to the configuration diagram shown in FIG. 1.

<ALD Apparatus>

As shown in the figure, the ALD apparatus 10 is a sheet feed type apparatus including a treatment chamber 11 in which to conduct a film forming treatment of a substrate S to be treated. The treatment chamber 11 has a stage 12 on which to mount and hold the substrate S, for example at a bottom portion thereof, and the stage 12 is provided with a heater (omitted in the figure) for heating the substrate S. In addition, for example on the lower side of the treatment chamber 11, an exhaust pipe 13 is connected for removing surplus gas and reaction products. A vacuum pump 14 is connected to the exhaust pipe 13, and a valve 13a whose opening can be controllable is provided between the vacuum pump 14 and the treatment chamber 11. The pressure inside the treatment chamber 11 can be reduced by operating the vacuum pump 14.

In addition, for example on the upper side of the treatment chamber 11, a plurality or gas supply pipes provided on a gas basis are connected, so as to supply gases into the treatment chamber 11. Incidentally, though omitted in the figure, a shower head type diffuser plate is provided oppositely to the stage 12 in the treatment chamber 11 so that the supplied gases are supplied to the whole area of the substrate S mounted and held on the stage 12.

Since a hafnium silicate film is to be formed, the plurality of gas supply pipes include a raw material gas supply pipe 15 for supplying tetrakis(methylethylamino)hafnium (Hf [N(CH₃)(C₂H₅)]₄) containing Hf atoms, a raw material gas supply pipe 16 for supplying tetrakis(methylethylamino)silicon (Si[N(CH₃)(C₂H₅)]₄) containing Si atoms, and an oxidizing gas supply pipe 17 for supplying an oxidizing gas composed of ozone, for example. In addition to the above, an inert gas supply pipe 18 for supplying an inert gas in a purging step is provided, as will be described later.

As above-mentioned, the raw material gas supply pipe 15 is connected at its one end to the treatment chamber 11, and is connected at its other end to a cylinder 15a in which the raw material gas containing Hf atoms is reserved. In addition, the raw material gas supply pipe 15 is provided with a flow rate regulator 15b and an ON/OFF valve 15c in this order from the cylinder 15a side.

The raw material gas supply pipe 16 is configured in the same manner as the raw material gas supply pipe 15, is connected at its one end to the treatment chamber 11, and is connected at its other end to a cylinder 16a in which a raw material gas containing Si atoms is reserved. Besides, the raw material gas supply pipe 16 is provided with a flow rate regulator 16b and an ON/OFF valve 16c in this order from the cylinder 16a side.

The oxidizing gas supply pipe 17 is connected at its one end to the treatment chamber 11, and is connected at its other end to a cylinder 17a in which oxygen (O₂) gas is reserved. The oxidizing gas supply pipe 17 is provided with an ozone gas generator 17b, a flow rate regulator 17c and a valve 17d in this order from the cylinder 17a side. The 02 gas supplied from the cylinder 17a into the oxidizing gas supply pipe 17 is introduced into the ozone gas generator 17b, whereby part thereof is converted into O₃ gas, which is supplied into the treatment chamber 11 together with the O₂ gas.

Further, the inert gas supply pipe 18 is connected at its one end to the treatment chamber 11, and is connected at its other end to a cylinder 18a in which an inert gas such as argon (Ar) is reserved. In addition, the inert gas supply pipe 18 is provided with a flow rate regulator 18b and an ON/OFF valve 18c in this order from the cylinder 18a side.

<Method of Forming Thin Film>

Now, the method of forming a hafnium silicate film by use of the ALD apparatus 10 as above will be described below.

First, a substrate on which to form a capacitor insulation film composed of a hafnium silicate film will be described. As shown in FIG. 2, the substrate 21 formed of single crystal silicon, for example, is provided with a deep type trench 23 formed from SiN, for example, by etching using a hard mask 22 as a mask. A lower electrode (omitted in the figure) formed by a solid phase diffusion process is provided on the inner wall of a lower portion of the trench 23.

The surface of the substrate 21 in this state is subjected to a cleaning treatment using a 0.1% hydrogen fluoride (HF) solution, for example, so as to remove a natural oxide film (SiO₂ film) formed on the inside wall surfaces of the trench 23. Thereafter, a nitriding treatment is conducted at 800° C., to form a silicon nitride layer (omitted in the figure) on the inside wall surfaces of the trench 23. This step is carried out for suppressing the diffusion of oxygen into the substrate 21, and the silicon nitride layer is formed in a film thickness of 1 nm or less. As a result, the inside wall of the trench 23 is in the state of being terminated by hydrogen atoms (H) of amino (NH₂) groups.

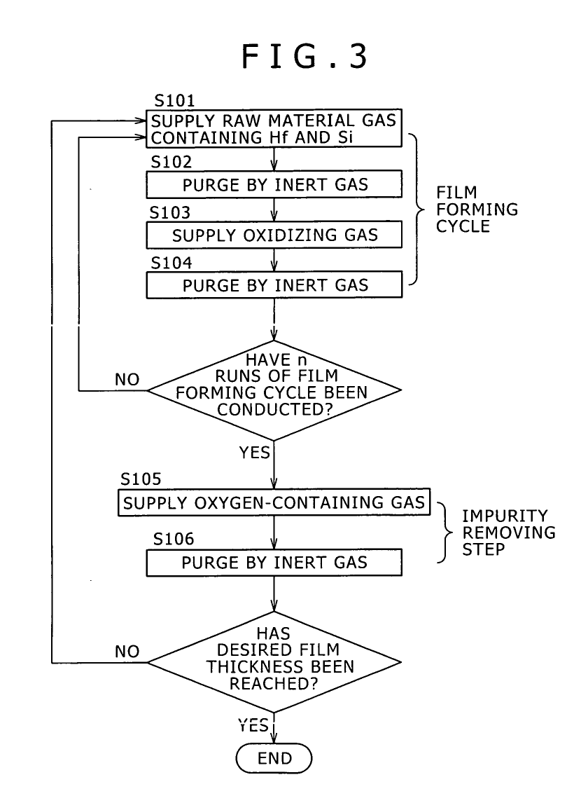

The substrate 21 in this state is mounted and held on the stage 12 in the treatment chamber 11 of the ALD apparatus 10 described referring to FIG. 1 above. Namely, the substrate S to be treated in FIG. 1 is the substrate 21. Then, by the ALD process, a capacitor insulation film composed of a hafnium silicate film is formed on the hard mask 22 in the state of covering the inside wall of the trench 23 in the substrate 21. The method of forming the capacitor insulation film will be described based on the flowchart shown in FIG. 3. Incidentally, the ALD apparatus used for the film formation is configured as shown in FIG. 1. Besides, the total quantity of gases in each of the steps which will be described later is constant, unless otherwise specified.

First, for example, the pressure inside the treatment chamber 11 and the temperature of the substrate 21 on which to form the hafnium silicate film are controlled. Incidentally, the pressure inside the treatment chamber 11 corresponds to the pressure of the treatment atmosphere as set forth in appended claims. Here, as above-mentioned, Hf[N(CH₃)(C₂H₅)]₄ and Si[N(CH₃)(C₂H₅)]₄ are used as the raw material gases, and these raw material gases are liable to be thermally decomposed in the gaseous phase when the pressure inside the treatment chamber 11 is in excess of 532 Pa or the temperature of the substrate 21 is higher than 400° C., so that the pressure inside the treatment chamber 11 is set to be not more than 532 Pa and the temperature of the substrate 21 is set to be not more than 400° C. In this case, the film forming rate of the raw material gases is higher as the pressure inside the treatment chamber 11 and the temperature of the substrate 21 are higher in the respective ranges. In view of this, it is preferable to set the pressure inside the treatment chamber 11 to within the range of 266 to 532 Pa and to set the temperature of the substrate 21 to within the range of 300 to 400° C. Here, the pressure inside the treatment chamber 11 is set at 532 Pa, and the temperature of the substrate 21 is set at 400° C. by regulating the temperature of the stage 12. In each of the steps which will be described later, the temperature of the substrate 21 is kept constant.

After the temperature of the substrate 21 has become stable, the raw material gas containing hafnium (Hf) atoms (Hf[N(CH₃)(C₂H₅)]₄) is supplied from the raw material gas supply pipe 15, and the raw material gas containing silicon (Si) atoms (Si[N(CH₃)(C₂H₅)]₄) is supplied from the raw material gas supply pipe 16 (S101).

As a result, H in the terminal NH₂ groups at the inside wall surfaces of the trench 23 is replaced by the raw material gas component, i.e., Hf[N(CH₃)(C₂H₅)]₃ or Si[N(CH₃)(C₂H₅)]₃, to be chemically adsorbed onto the nitrogen atom (N). Therefore, a layer containing Hf atoms and Si atoms is formed on the inside wall surfaces of the trench 23, and N-ethylmethylamine (C₂H₅NHCH₃) is produced as a reaction product.

Incidentally, here, the Hf atom-containing raw material gas and the Si atom-containing raw material gas are supplied in the same step; however, either one of the Hf atom-containing raw material gas and the Si atom-containing raw material gas may be supplied precedingly. For example, where the Hf atom-containing raw material gas is supplied precedingly, the Si atom-containing raw material gas is supplied after a purging step, an oxidizing gas supplying step and a purging step are sequentially conducted, and, then, a purging step, an oxidizing gas supplying step and a purging step are conducted sequentially. As a result, layers of Hf oxide and layers of Si oxide are formed in an alternately laminated form.

After the raw material gases are supplied as above, an inert gas composed of Ar is supplied into the treatment chamber 11 for 5 sec in the condition where the pressure inside the treatment chamber 11 is maintained, to purge the unreacted raw material gases. By this purging, the above-mentioned reaction products are also removed. Incidentally, while the inert gas composed of Ar is used here, other inert gases may also be used, for example, helium (He), neon (Ne), nitrogen (N₂), or hydrogen (H₂). Incidentally, both nitrogen (N₂) and hydrogen (H₂) are also included in the inert gases.

Subsequently, in the condition where the pressure inside the treatment chamber 11 is maintained, an oxidizing gas composed of O₃, for example, is supplied into the treatment chamber 11 as a carrier gas for 5 sec (S103). As a result of this, methylethylamino groups (N(CH₃)(C₂H₅)) in the raw material gas components (Hf[N(CH₃)(C₂H₅)]₃ and Si[N(CH₃) (C₂H₅)]₃) adsorbed on the inside wall surfaces of the trench 23 are replaced by oxygen (O) atoms, respectively. This results in that a layer of oxygen (O) atoms in the state of being adsorbed on Hf atom and Si atom is formed on the inside wall surfaces of the trench 23, and, hence, a layer containing Hf oxide and Si oxide is formed. Besides, in this case, N-ethylmethylamine (C₂H₅NHCH₃) is produced as a reaction product.

Incidentally, while O₃ is used here as the oxidizing gas, it suffices for the oxidizing gas to be a compound capable of reacting with the raw material gas component to form a layer of O atoms, and, therefore, the oxidizing gas may be hydrogen peroxide (H₂O₂), water (H₂O) or heavy water (D₂O).

Next, an inert gas composed of Ar is supplied into the treatment chamber 11 for 5 sec (S104). Incidentally, while Ar is used as the inert gas here, He, Ne, N₂, H₂ or the like may also be used, in the same manner as in the above-described first purging step.

When the film forming cycle composed of the raw material gas supplying step (S101) to the purging step (S104) is carried out once as above-mentioned, a thin film having a thickness of 0.1 to 0.2 nm is formed. In this embodiment, the step of removing impurities present in the film is conducted, for example, every 10 runs of the film forming cycle which is repeated. Therefore, n in the decision step “Have n runs of film forming step been conducted?” subsequent to the purging step (S104) in the flowchart shown in FIG. 3 is 10. By repeating the film forming cycle 10 times, a thin film having a thickness of 1 to 2 nm is formed.

Then, after the film forming cycle is repeated 10 times, an impurity removing step is conducted which is composed of a step of supplying an oxygen-containing gas into the treatment chamber 11 so as to oxidize the impurities present in the thin film formed (S105) and a step of supplying an inert gas into the treatment chamber 11 so as to purge the unreacted oxygen-containing gas and the oxidized impurities (S106).

Here, as the oxygen-containing gas used in the oxygen-containing gas supplying step (S105), there can be used O₃, O₂, O₂ plasma, H₂O, H₂O₂, and D₂O. Particularly, where Hf[N(CH₃)(C₂H₅)]₄ and Si[N(CH₃)(C₂H₅)]₄ are used as the raw material gases as above, it is preferable to use O₃, O₂, or O₂ plasma, by which C and H liable to remain as impurities can be efficiently removed in the form of CO₂ and H₂O, respectively. In the case of using the O₂ plasma, O₂ gas is supplied and is converted into a plasma in the treatment chamber 11 by remote plasma.

Here, the O₃ gas and O₂ gas as a carrier gas which are supplied from the oxidizing gas supply pipe 17 are used as the oxygen-containing gas. Where the same gas as the oxidizing gas used in the film forming cycle is used here as the oxygen-containing gas, modifications such as addition of a gas supply pipe to the ALD apparatus 10 are not needed, which is favorable. As a result, C or H as impurity arising from the raw material gases remaining in the film is oxidized to be CO₂ or H₂O.

Here, the oxygen-containing gas supplying step (S105) is conducted under the conditions of the treatment atmosphere pressure of 599 to 1330 Pa, a gas flow rate of 350 to 1000 cm³/min, a treatment time of 5 to 600 sec, and a substrate temperature of 300 to 500° C. At least one of the pressure inside the treatment chamber 11, the gas flow rate, and the temperature of the substrate 21 is set higher than that in the oxidizing gas supplying step (S103), or the treatment time is set longer than that in the oxidizing gas supplying step (S103), whereby the impurity oxidizing effect can be enhanced. Among others, an enhancement of the pressure inside the treatment chamber 11 is preferred, since the impurities are thereby oxidized efficiently. Besides, some of the above-mentioned film forming conditions may be carried out in combination.

In addition, in the case where the same gas is supplied in the oxidizing gas supplying step (S103) and in the oxygen-containing gas supplying step (S105), the concentration of the oxygen-containing gas may be set higher than the concentration of the oxidizing gas, whereby the impurities are oxidized efficiently. For example, where O₃ gas is used both as the oxidizing gas and as the oxygen-containing gas, it is preferable that the oxidizing gas supplying step (S103) is conducted by use of O₃ gas in a concentration of 250 g/cm³ and the oxygen-containing gas supplying step (S105) is conducted by use of O₃ gas in a concentration higher than 250 g/cm³.

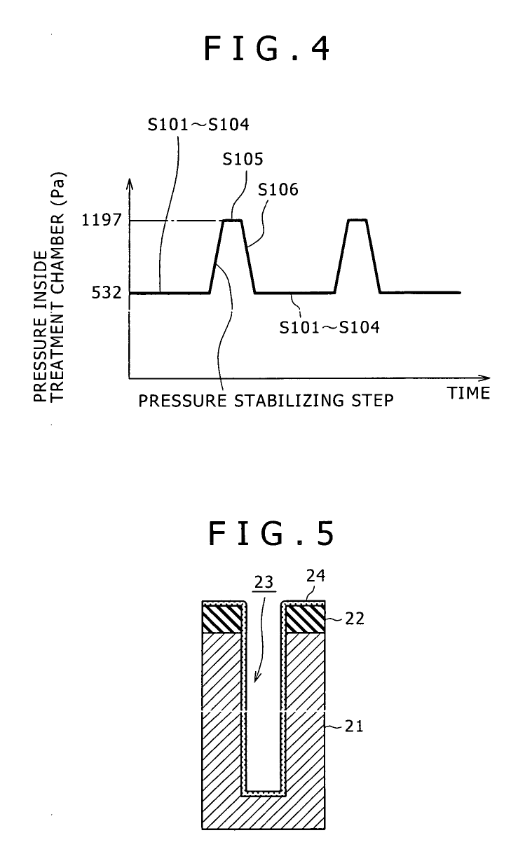

Here, for example, the pressure inside the treatment chamber 11 in the oxygen-containing gas supplying step (S105) is set at 1197 Pa which is higher than the pressure (532 Pa) inside the treatment chamber 11 in the oxidizing gas supplying step (S103), and the treatment time of the oxygen-containing gas supplying step (S105) is set at 60 sec which is longer than the treatment time (5 to 10 sec) of the oxidizing gas supplying step (S103). In this case, as shown in the graph of the variation of the pressure inside the treatment chamber 11 in FIG. 4, a pressure stabilizing step of supplying an inert gas composed of Ar, for example, for 15 sec so as to raise the pressure inside the treatment chamber 11 from 532 Pa to 1197 Pa is conducted after the film forming cycle. Incidentally, while the pressure stabilizing step is provided separately from the purging step (S104) in the film forming cycle, the pressure stabilizing step may be combined with the purging step (S104).

As has been described above, after the oxygen-containing gas supplying step (S105) is conducted, an inert gas is supplied into the treatment chamber 11 for 15 sec, to thereby purge the unreacted oxygen-containing gas and the oxidized impurities such as CO₂ and H₂O(S106) Then, as will be described later, the raw material gas supplying step (S101) is again carried out after the purging step (S106), so that, during the purging step, the pressure inside the treatment chamber 11 is returned to the pressure inside the treatment chamber 11 in the raw material gas supplying step (S101), namely, 532 Pa, and the pressure is stabilized.

Thereafter, the film forming cycle ranging from the raw material gas supplying step (S101) to the purging step (S104) is repeated, and, every 10 runs of the film forming cycle, the impurity removing step composed of the oxygen-containing gas supplying step (105) and the inert gas supplying step (S106) is carried out. The repetition number of the film forming cycle is calculated based on the thickness of the thin film formed by one film forming cycle and the desired film thickness. The film forming cycle is repeated the calculated number of times, then the impurity removing step is conducted, and thereafter it is judged whether a predetermined film thickness is obtained or not. When the film is found to have the predetermined thickness, the film forming process is finished; on the other hand, when the film thickness obtained is less than the predetermined film thickness, the film forming cycle is again repeated, and finally the impurity removing step is carried out.

Incidentally, while the impurity removing step is here carried out once every 10 runs of the film forming cycle, namely, once every time when a film thickness of 1 to 2 nm is obtained, it is possible, by conducting the impurity removing step at a shorter interval, to remove the impurities in the film more efficiently. Besides, where throughput is demanded more keenly than film quality, the impurity removing step may be conducted at a longer interval (i.e., every more than 10 runs of the film forming cycle) to thereby minimize the reduction in throughput. It should be noted here, however, if the impurity removing step is conducted after the hafnium silicate film has become thicker than 2 nm, the impurity removing effect is lowered. In this embodiment, a hafnium silicate film having a thickness of 0.1 to 0.2 nm is formed by one film forming cycle, and, therefore, it is preferable to carry out the impurity removing step at least once for every 10 to 20 runs of the film forming cycle.

As a result of this, as shown in FIG. 5, a capacitor insulation film 24 composed of the hafnium silicate film having the desired thickness is formed on the hard mask 22 in the state of covering the inside wall surfaces of the trench 23. Thereafter, ammonium gas (NH₃) is supplied into the treatment chamber 11, and a heat treatment is conducted, to thereby nitride the capacitor insulation film 24. By this, the capacitor insulation film 24 is converted into a hafnium silicate nitride (HfSiON) film.

The subsequent steps are conducted in the same manner as in the ordinary trench capacitor forming method. Specifically, an upper electrode (omitted in the figure) composed of polysilicon, for example, is formed on the capacitor insulation film 24 in the state of filling up the trench 23, to obtain a trench capacitor.

According to such a method of forming the capacitor insulation film 24, in the oxygen-containing gas supplying step (S105), O₃ gas and O₂ gas are supplied into the same treatment chamber 11 as that for the film forming cycle, whereby the impurities such as C and H arising from the raw material gases are oxidized to be CO₂, H₂O and the like. Thereafter, in the purging step using an inert gas (S106), the oxidized impurities are purged together with the unreacted oxygen-containing gas. This makes it possible to carry out the impurity removing step in the same treatment chamber 11 as that used for the film forming cycle. Therefore, throughput can be enhanced, as compared with the case where the impurity removing step is conducted in another chamber.

In addition, since the impurity removing step is carried out by use of the oxygen-containing gas, a better situation as compared with the case of using NH₃ gas is obtained, in which oxygen atoms would not be replaced by nitrogen atoms during film formation, and a hafnium silicate film having a lowered concentration of impurities can be formed. This makes it possible to suppress the leakage current arising from the impurities in the film through the trap level. Therefore, it is possible to enhance the yield of the device being manufactured.

Incidentally, an example in which impurities such as C and H are generated because of the use of Hf[N(CH₃)(C₂H₅)]₄ and Si[N(CH₃)(C₂H₅)]₄ as the raw material gases has been described in this embodiment, an impurity including chlorine (Cl) may arise from raw material gases. In this case, H₂O₂, H₂O or D₂O is used as the oxygen-containing gas, to thereby remove Cl in the form of HCl.

In addition, an example of forming the capacitor insulation film in the trench of a trench capacitor has been described in this embodiment, the present invention is not limited to this example but is applicable also to the case of forming a capacitor insulation film by an ALD process in the state of covering a lower electrode having a fin type or crown type recess-projection combination, and the case of forming a capacitor insulation film on a flat plate.

### Second Embodiment

In this embodiment, description will be made of an example in which a gate insulation film of an n-channel MOS field effect transistor (nMOSFET) is formed by an ALD process, in the method of manufacturing a semiconductor device by use of the first method of forming a thin film according to the present invention. As the gate insulation film, a hafnium silicate (HfSiOₓ) film is formed, in the same manner as in the first embodiment. Here, in forming the hafnium silicate film, the ALD apparatus described referring to FIG. 1 is used.

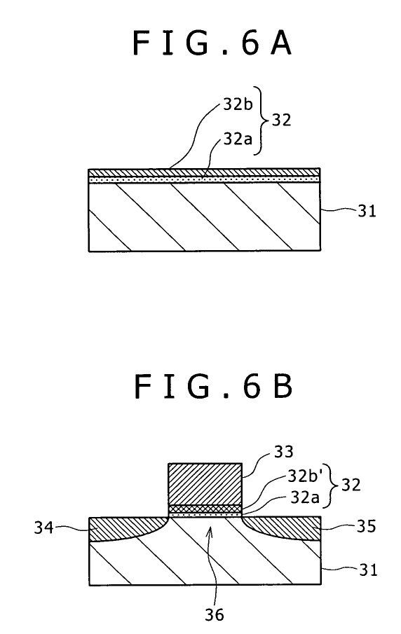

First, as shown in FIG. 6A, an SC2 treatment (cleaning with aqueous hydrochloric acid-hydrogen peroxide solution) is applied to the surface of a substrate 31 formed of single crystal silicon, to form an interface layer 32a composed of SiO₂. The interface layer 32a is formed to have a film thickness of about 1 nm, independent of the film forming technique, and is further grown through the subsequent film forming treatment and annealing treatment; therefore, it is difficult to control the film thickness of the interface layer 32a. The interface layer 32a and a hafnium silicate film formed on the interface layer 32a in a latter step constitute a gate insulation film. The presence of the interface layer 32a between the substrate 31 and the hafnium silicate film enhances the interface characteristics between the gate insulation film and the substrate 31. Here, the interface layer 32a is formed in a film thickness of 1.3 nm.

Incidentally, while the interface layer 32a is formed by applying the SC2 treatment to the surface of the substrate 31 here, another method may be adopted in which a step of removing a natural oxide (SiO₂) film on the surface of the substrate 31 by use of an HF solution is conducted, and thereafter the hafnium silicate film is formed; in this case, also, in the oxidizing gas supplying step in the film forming cycle, the surface of the substrate 31 and the oxidizing gas react with each other, whereby the interface layer 32a is formed in a film thickness equivalent to that in the case of the SC2 treatment.

Next, the substrate 31 in the state of being provided with the interface layer 32a is mounted and held on the stage 12 in the treatment chamber 11 of the ALD apparatus 10 as described referring to FIG. 1. Namely, the substrate S to be treated in FIG. 1 is the substrate 31. Then, a hafnium silicate film 32b is formed on the interface layer 32a by the ALD process, to obtain a gate insulation film 32 composed of the interface layer 32a and the hafnium silicate film 32b. Here, the gate insulation film 32 is so formed as to have an equivalent oxide film thickness (EOT) of about 2 nm.

The step of forming the hafnium silicate film 32b is composed by repeating the film forming cycle ranging from the raw material gas supplying step (S101) to the purging step (S104) based on the flowchart described referring to FIG. 3, in the same manner as in the first embodiment.

Here, as will be described later, when the impurity removing step is conducted after the film forming cycle, the film thickness of the interface layer 32a is increased; therefore, for maintaining the EOT of the gate insulation film 32 at about 2 nm, it is preferable to increase the composition ratio of Hf in the hafnium silicate film 32b (Hf/(Hf+Si)) so as to raise the dielectric constant, as compared with the case where the impurity removing step is not provided.

Therefore, in the raw material gas supplying step (S101) in the film forming cycle, the flow rate ratio or concentration of the Hf atom-containing raw material gas (Hf[N(CH₃)(C₂H₅)]₄) is raised, as compared with the case where the impurity removing step is not provided, whereby the composition ratio of Hf in the hafnium silicate film 32b is controlled to be about 52 to 55%.

When the film forming cycle ranging from the raw material gas supplying step (S101) to the purging step (S104) is conducted once, a thin film having a thickness of 0.1 to 0.2 nm is formed. In addition, the impurity removing step for removing the impurities present in the film is conducted every 10 runs, for example, of the film forming cycle being repeated, in the same manner as in the first embodiment. Accordingly, n in the decision step “Have n runs of film forming step been conducted?” subsequent to the purging step (S104) in the flowchart shown in FIG. 3 is 10. By repeating the film forming cycle 10 times, a thin film having a thickness of 1 to 2 nm is formed.

After the film forming cycle is repeated 10 times, an impurity removing step composed of a step of supplying an oxygen-containing gas into the treatment chamber 11 so as to oxidize the impurities in the film formed (S105) and a step of supplying an inert gas into the treatment chamber 11 so as to purge the unreacted oxygen-containing gas and the oxidized impurities (S106) is carried out.

In this case, in the oxygen-containing gas supplying step (S105), the pressure inside the treatment chamber 11 is set at 1197 Pa which is higher than the pressure (532 Pa) inside the treatment chamber 11 in the oxidizing gas supplying step (S103), and O₃ gas and O₂ gas are supplied under this condition, whereby the impurities in the film arising from the raw material gas are oxidized. Thereafter, in a purging step using an inert gas, the oxidized impurities are purged together with the unreacted oxygen-containing gas. By this, the impurities in the hafnium silicate film 32b are removed.

Besides, with the pressure inside the treatment chamber 11 in the oxygen-containing gas supplying step (S105) set to be higher than that in the oxidizing gas supplying step (S103), oxygen in the oxygen-containing gas reacts with the surface of the substrate 31, whereby the film thickness of the interface layer 32a composed of SiO₂ is increased. This suppresses the Coulomb scattering which arises from the fixed electric charges in the hafnium silicate layer 32b, and restrains electric charges from being injected from a channel region formed on the surface side of the substrate 31 in a latter step into the hafnium silicate film 32b through the interface layer 32a.

In the oxygen-containing gas supplying step (S105), at least one of the pressure inside the treatment chamber, the gas flow rate, and the temperature of the substrate 31 is set to be higher than that in the oxidizing gas supplying step (S103), or the treatment time is set to be longer than that of the oxidizing gas supplying step (S103), whereby the film thickness of the interface layer 32a is increased. Among others, the raising of the pressure inside the treatment chamber 11 is preferable, since the film thickness of the interface layer 32a can be increased efficiently.

In this embodiment, the film thickness of the interface layer 32a is determined by controlling the pressure inside the treatment chamber 11 in the oxygen-containing gas supplying step (S105) and the number of times the impurity removing step is conducted. The film thickness of the interface layer 32a is preferably such a film thickness that the Coulomb scattering arising from the fixed electric charges in the hafnium silicate film 32b is suppressed, the injection of electric charges from the channel region into the hafnium silicate film 32b is restrained, and the desired EOT can be obtained. Where the EOT of the gate insulation film 32 is controlled to be about 2 nm as in this embodiment, the film thickness of the interface layer 32a is preferably about 1.5 nm. Here, the film thickness of the interface layer 32a is increased from 1.3 nm to 1.5 nm, by conducting the impurity removing step.

Thereafter, the film forming cycle ranging from the raw material gas supplying step (S101) to the purging step (S104) is repeated, and the impurity removing step is conducted every 10 runs of the film forming cycle. The repetition number of the film forming cycle is calculated based on the thickness of the thin film formed by one film forming cycle and the desired film thickness. After the film forming cycle is repeated the calculated number of times and the impurity removing step is conducted, it is judged whether the desired film thickness has been obtained. When the film thickness has reached the desired film thickness, the film formation is finished; on the other hand, when the film thickness has not yet reached the desired film thickness, the film forming cycle is again repeated, and finally the impurity removing step is carried out.

Incidentally, while an example in which the impurity removing step is conducted once every time when the film forming cycle is repeated 10 times has been described here, the present invention is not limited to this example. It should be noted, however, that where the hafnium silicate film 32b is formed as the gate insulation film 32, the thickness of the hafnium silicate film 32b is as small as about 2 nm, so that the impurity removing effect can be obtained even after the formation of the film; therefore, it is preferable to determine the number of times of the impurity removing step according to the film thickness of the interface layer 32a. Here, since the hafnium silicate film 32b is formed in a thickness of 2 nm, the repetition number of the film forming cycle is 10 to 20, and the number of times of the impurity removing step which is conducted every 10 runs of the film forming cycle is in the range of 1 to 2.

In the above-mentioned manner, the gate insulation film 32 composed of the interface layer 32a and the hafnium silicate film 32b is formed on the surface of the substrate 31. Thereafter, as shown in FIG. 6B, the gate insulation film 32 is subjected to a plasma nitriding treatment. This converts the hafnium silicate film 32 in the gate insulation film 32 to a hafnium silicate nitride (HfSiON) film 32b′. Thereafter, for enhancing the interface characteristics deteriorated due to the plasma nitriding treatment, an RTA (Rapid Thermal Annealing) treatment in a nitrogen (N₂) atmosphere at 1000° C. is carried out.

The subsequent steps are conducted in the same manner as in the ordinary nMOSFET manufacturing method. Specifically, a gate electrode 33 composed of polysilicon (poly-Si), for example, is patternedly formed on the gate insulation film 32, and then source/drain regions 34 and 35 are formed in the substrate 31 on both sides of the gate electrode 33 by the ordinary technology of forming source/drain regions of nMOSFET. This results in the condition where a channel region 36 is provided between the source/drain regions 34 and 35. In this manner, a semiconductor device composed of nMOSFET can be obtained.

According to such a method of forming the gate insulation film 32, after the impurities in the film arising from the raw material gas are oxidized in an oxygen-containing gas supplying step (S105), the oxidized impurities are purged together with the oxygen-containing gas in a purging step using an inert gas (S106). This makes it possible to conduct the impurity removing treatment in the same treatment chamber 11 as that used for the film forming cycle. Therefore, throughput can be enhanced, as compared with the case where the impurity removing treatment is conducted in another chamber.

Besides, since the impurity removing treatment is carried out by use of the oxygen-containing gas, a better situation as compared with the case of using NH₃ gas is obtained in which oxygen atoms would not be replaced by nitrogen atoms during film formation, and the hafnium silicate film lowered in impurity concentration can be formed. This makes it possible to suppress the leakage current arising from the impurities in the film through the trap level. Therefore, it is possible to enhance the yield of the device being manufactured.

Further, according to this embodiment, the interface layer 32a is formed to be thicker, as compared with the case where the impurity removing step is not provided. Therefore, the Coulomb scattering due to fixed electric charges in the hafnium silicate nitride film 32b′ is suppressed, so that the influence thereof on the electric charges in the channel region 36 is suppressed, and the carrier mobility can be enhanced. Besides, with the interface layer 32a formed to be thicker, the electric charges in the channel region 36 are restrained from being trapped by the hafnium silicate nitride film 32b′, and the threshold voltage is prevented from being varied, so that device reliability such as PBTI (Positive Bias Temperature Instability) can be improved. Further, with the dielectric constant of the hafnium silicate film 32b raised attendant on the increase in the film thickness of the interface layer 32a, the EOT is maintained, so that the merit of scaling is not spoiled. Therefore, it is possible to favorably cope with processes for CMOS devices of the 45 nm generation and latter generations.

Incidentally, while an example in which the gate electrode 33 is formed of poly-Si has been described in this embodiment, the present invention is not limited to this example but is applicable also to the case where the gate electrode 33 is formed of a metal or a full-silicide. In addition, while the nMOSFET manufacturing method has been described as an example in this embodiment, the present invention is applicable also to the case of manufacturing a p-channel type MOS field effect transistor (pMOSFET).

### Third Embodiment

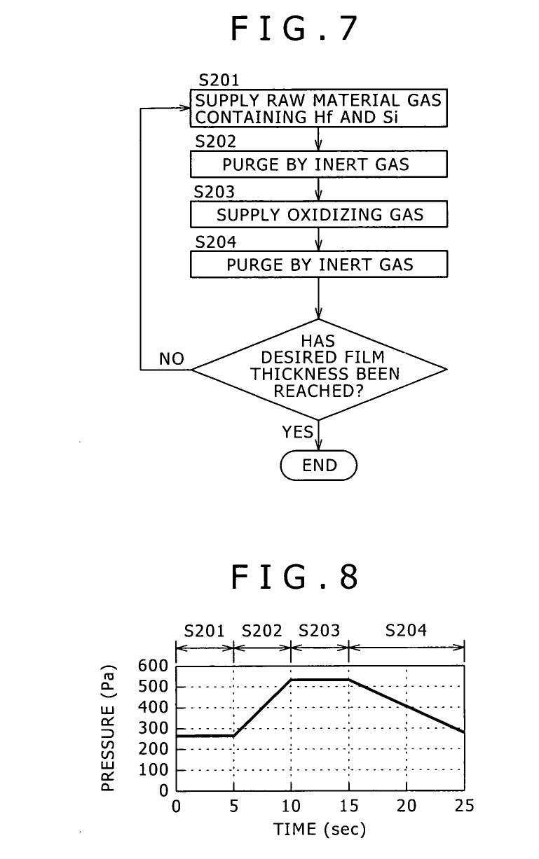

In this embodiment, description will be made of an example in which a capacitor insulation film of a deep trench type trench capacitor is formed by an ALD process, in the method of manufacturing a semiconductor device by use of the second method of forming a thin film according to the present invention. In this embodiment, the same substrate as in the first embodiment (see FIG. 2) is used, and description will be made referring to the flowchart shown in FIG. 7 and the graph of the variation in pressure inside a treatment chamber shown in FIG. 8. Besides, an ALD apparatus used for film formation is configured as shown in FIG. 1.

First, in the same manner as in the first embodiment, a pretreatment of a substrate 21 is conducted, and thereafter the substrate 21 is mounted and held on a stage 12 in a treatment chamber 11 of an ALD apparatus 10. Then, a capacitor insulation film composed of a hafnium silicate film is formed on a hard mask 22 in the state of covering the inside wall of a trench 23 in the substrate 21 by the ALD process.

In this case, the pressure inside the treatment chamber 11 is set at, for example, 266 Pa (FIG. 8), and the temperature inside the treatment chamber 11 and the temperature of the stage 12 on which to mount the substrate 21 are set to 400° C. Here, in the steps described later, the temperature of the substrate 21 is kept constant. After the temperature of the substrate 21 becomes stable, an Hf atom-containing raw material gas (Hf[N(CH₃)(C₂H₅)]₄) is supplied from a raw material gas supply pipe 15, and an Si atom-containing raw material gas (Si[N(CH₃)(C₂H₅)]₄) is supplied from a raw material gas supply pipe 16 (S201). As a result, a layer composed of Hf atoms or Si atoms is formed on the inside wall surface of the trench 23, and N-ethylmethylamine (C₂H₅NHCH₃) is produced as a reaction product.

Next, an inert gas composed of Ar is supplied into the treatment chamber 11 for 5 sec so as to purge the unreacted raw material gases and the reaction product (S202). In this case, an oxidizing gas supplying step as the subsequent step is carried out at a pressure of 532 Pa as will be described later; in view of this, the pressure is raised from 266 Pa to 532 Pa during the purging step which continues for 5 sec.

Subsequently, under the condition where the pressure inside the treatment chamber 11 is raised to, for example, 532 Pa which is higher than the pressure inside the treatment chamber 11 in the raw material gas supplying step (S201) (FIG. 8), an oxidizing gas composed of O₃, for example, is supplied for 5 sec by using O₂ as a carrier gas (S203). As a result, a layer of oxygen (O) atoms in the state of being adsorbed onto Hf and Si atoms is formed on the inside wall surface of the trench 23, and N-ethylmethylamine (C₂H₅NHCH₃) is produced as a reaction product.

Here, in this embodiment, the pressure inside the treatment chamber 11 in the oxidizing gas supplying step (S203) is set to be higher than the pressure inside the treatment chamber 11 in the raw material gas supplying step (S201). Specifically, the pressure inside the treatment chamber 11 is set higher than the pressure inside the treatment chamber 11 in the raw material gas supplying step (S201), in the range of up to 1330 Pa. This makes it possible to form the layer of oxygen (O) atoms and to oxidize the impurities such as C and H arising from the raw material gases to CO₂, H₂O and the like.

Incidentally, while O₃ is used here as the oxidizing gas, the oxidizing gas may be any compound that can form the layer of O atoms; for example, the oxidizing gas may be hydrogen peroxide (H₂O₂), water (H₂O) or heavy water (D₂O). It should be noted, however, the impurities can be removed most efficiently when O₃ gas is used, and, therefore, it is preferable to use O₃ gas as the oxidizing gas. The impurities such as C and H arising from the raw material gases are oxidized to CO₂, H₂O and the like, also by O₂ used as a carrier gas for the O₃ gas, so that the impurities are oxidized efficiently.

Next, an inert gas composed of Ar is supplied into the treatment chamber 11 for 10 sec, to purge the unreacted oxidizing gas and the oxidized impurities (S204). Here, since the raw material gas supplying step (S201) is again conducted after the purging step (S204) as will be described later, the pressure inside the treatment chamber 11 is lowered from 532 Pa to 266 Pa during the purging step (S204), by regulating the opening of a valve 13a provided in an exhaust pipe 13.

Thereafter, the film forming cycle ranging from the raw material gas supplying step (S201) to the purging step (S204) is repeated a plurality of times until the desired film thickness is obtained, whereby the hafnium silicate film is formed. The repetition number of the film forming cycle is calculated in the same manner as in the first embodiment. Then, the film forming cycle is repeated the calculated number of times, and it is judged whether the predetermined film thickness has been reached. When the predetermined film thickness has been obtained, the film formation is finished; on the other hand, when the predetermined film thickness has not yet been reached, the film forming cycle is again repeated.

As a result of this, a capacitor insulation film 24 composed of hafnium silicate and having the desired thickness is formed on a hard mask 22 in the state of covering the inside wall surface of the trench 23, as shown in FIG. 5. The subsequent steps are conducted in the same manner as in the first embodiment.

According to such a method of forming a thin film, in the oxidizing gas supplying step (S203), the oxidizing gas is supplied into the treatment atmosphere under the condition where the pressure inside the treatment chamber 11 is set higher than that in the raw material gas supplying step (S201), whereby a layer of O atoms is formed, and the impurities such as C and H arising from the raw material gases are oxidized to CO₂, H₂O and the like. Thereafter, the oxidized impurities are purged together with the unreacted oxidizing gas in the purging step (S204) using an inert gas. This makes it possible to remove the impurities during the film forming cycle. Therefore, throughput can be enhanced, as compared with the case of conducting the impurity removing treatment in another chamber.

In addition, since the impurity removing treatment is carried out using the oxidizing gas, a better situation as compared with the case of using NH₃ gas is obtained in which oxygen atoms would not be replaced by nitrogen atoms during film formation, and a hafnium silicate film lowered in impurity concentration can be formed. This makes it possible to suppress the leakage current arising from the impurities in the film through the trap level. Therefore, it is possible to enhance the yield of the device being manufactured.

Incidentally, in this embodiment, description has been made of an example in which the pressure inside the treatment chamber 11 in the oxidizing gas supplying step (S203) is set to be higher than the pressure inside the treatment chamber 11 in the raw material gas supplying step (S201). However, the present invention is not limited to the example, and, alternatively, the temperature of the substrate 21 in the oxidizing gas supplying step (S203) may be set to be higher than the temperature of the substrate 21 in the raw material gas supplying step (S201). In this case, the temperature of the substrate 21 in the oxidizing gas supplying step (S203) is set higher than the temperature of the substrate 21 in the raw material gas supplying step (S201), within the range of 300 to 500° C. Here, since the raw material gas supplying step (S201) is conducted at 400° C., the oxidizing gas supplying step (S203) is carried out at 500° C., for example. This ensures that the impurities arising from the raw material gases are removed efficiently.

In addition, both the pressure inside the treatment chamber 11 and the temperature of the substrate 21 in the oxidizing gas supplying step (S203) may be set to be respectively higher than the pressure inside the treatment chamber 11 and the temperature of the substrate 21 in the raw material gas supplying step (S201). In this case, the impurities arising from the raw material gases are removed more efficiently.

Besides, the first embodiment and the third embodiment may be carried out in combination. In this case, for example, the pressure inside the treatment chamber 11 in the oxidizing gas supplying step of the film forming cycle is set to be higher than the pressure inside the treatment chamber 11 in the raw material gas supplying step. In addition, the impurity removing step is conducted every time when the film forming cycle has been repeated a plurality of times.

### Fourth Embodiment

In this embodiment, description will be made of an example in which a gate insulation film of an nMOSFET is formed by an ALD process, in the method of manufacturing a semiconductor device by use of the second method of forming a thin film according to the present invention. As the gate insulation film, a hafnium silicate film is formed. Here, the ALD apparatus described referring to FIG. 1 is used in forming the hafnium silicate film.

First, as shown in FIG. 6A, the SC2 treatment is applied to the surface of a substrate 31 composed of single crystal silicon, whereby an interface layer 32a composed of SiO₂ is formed in a film thickness of about 1.3 nm. Next, the substrate 31 provided thereon with the interface layer 32a is mounted and held on the stage 12 in the treatment chamber 11 of the ALD apparatus 10 described referring to FIG. 1. Namely, the substrate S to be treated in FIG. 1 is the substrate 31. Then, by the ALD process, a hafnium silicate film 32b is formed on the interface layer 32a, to obtain a gate insulation film 32 composed of the interface layer 32a and the hafnium silicate film 32b. Here, the gate insulation film 32 is so formed as to have an equivalent oxide film thickness (EOT) of about 2 nm.

The step of forming the hafnium silicate film 32b is conducted by repeating the film forming cycle ranging from the raw material gas supplying step (S201) to the purging step (S204) based on the flowchart described referring to FIG. 7, in the same manner as in the third embodiment. Here, the hafnium silicate film 32b is formed in a thickness of 2 nm; therefore, since a thin film having a thickness of 0.1 to 0.2 nm is formed by one film forming cycle, the film forming cycle is repeated 10 to 20 times.

Here, with the pressure inside the treatment chamber 11 in the oxidizing gas supplying step (S203) set to be higher than the pressure (266 Pa) inside the treatment chamber 11 in the raw material gas supplying step (S201), the film thickness of the interface layer 32a is increased. For maintaining the EOT of the gate insulation film 32 at around 2 nm, it is preferable to increase the composition ratio of Hf in the hafnium silicate film (Hf/(Hf+Si)), as compared with the case where the pressure inside the treatment chamber 11 in the raw material gas supplying step (S201) and that in the oxidizing gas supplying step (S203) are equal, and thereby to raise the dielectric constant of the hafnium silicate film 32b.

Therefore, in the raw material gas supplying step (S201) of the film forming cycle, the flow rate or concentration of the Hf atom-containing raw material gas (Hf[N(CH₃)(C₂H₅)]₄) is raised, as compared with the case where the pressure inside the treatment chamber 11 in the raw material supplying step (S201) and that in the oxidizing gas supplying step (S203) are equal, whereby the composition ratio of Hf in the hafnium silicate film 32b is controlled to be about 52 to 55%.

Then, in the oxidizing gas supplying step (S203), O₃ gas and O₂ gas are supplied in the condition where the pressure inside the treatment chamber 11 is set at 532 Pa which is higher than the pressure inside the treatment chamber 11 in the raw material gas supplying step (S201), whereby a layer of O atoms is formed, and the impurities in the film arising from the raw material gases are oxidized.

Besides, with the pressure inside the treatment chamber 11 in the oxidizing gas supplying step (S203) set to be higher than that in the raw material gas supplying step (S201), oxygen in the oxidizing gas reacts with the surface of the substrate 31, whereby the interface layer 32a composed of SiO₂ is increased in film thickness. This suppresses the Coulomb scattering arising from the fixed electric charges in the hafnium silicate film 32b, and restrains electric charges from being injected from a channel region formed on the face side of the substrate 31 in a later step into the hafnium silicate film 32b through the interface layer 32a.

Incidentally, description is made here or an example in which the pressure inside the treatment chamber 11 in the oxidizing gas supplying step (S203) is set higher than that in the raw material gas supplying step (S201), the film thickness of the interface layer 32a is increased also by setting the temperature of the substrate 31 in the oxidizing gas supplying step (S203) to be higher than that in the raw material gas supplying step (S201).

In this embodiment, the film thickness of the interface layer 32a is determined by controlling the pressure inside the treatment chamber 11 in the oxidizing gas supplying step (S203). Here, like in the second embodiment, the EOT of the gate insulation film 32 is regulated to about 2 nm; therefore, it is preferable to set the film thickness of the interface layer 32a to about 1.5 nm, and, here, the film thickness of the interface layer 32a is increased from 1.3 nm to 1.5 nm.

In the above-mentioned manner, a gate insulation film 32 composed of the interface layer 32a and the hafnium silicate film 32b is formed on the surface of the substrate 31. Thereafter, as shown in FIG. 6B, a plasma nitriding treatment is applied to the gate insulation film 32. As a result, the hafnium silicate film 32 in the gate insulation film 32 is converted to a hafnium silicate nitride (HfSiON) film 32b′. Thereafter, an RTA treatment is conducted in an N₂ atmosphere at 1000° C. The subsequent steps are carried out in the same manner as in the ordinary nMOSFET manufacturing method.

According to such a method of forming the gate insulation film 32, in the oxidizing gas supplying step (S203), the oxidizing gas is supplied into the treatment atmosphere in the condition where the pressure inside the treatment chamber 11 is set higher than that in the raw material gas supplying step (S201), whereby a layer of O atoms is formed and the impurities are oxidized. Thereafter, in a purging step using an inert gas (S204), the oxidized impurities are purged together with the unreacted oxidizing gas. This makes it possible to remove the impurities during the film forming cycle. Therefore, throughput can be enhanced, as compared with the case where the impurity removing treatment is conducted in another chamber.

In addition, since the impurity removing treatment is carried out by use of the oxidizing gas, a better situation than in the case of NH₃ gas is obtained in which oxygen atoms would not be replaced by nitrogen atoms during film formation, and a hafnium silicate film lowered in impurity concentration can be formed. This makes it possible to suppress the leakage current arising from the impurities in the film through the trap level. Therefore, it is possible to enhance the yield of the device being manufactured.

Furthermore, according to this embodiment, the interface layer 32a can be made thicker in the film forming cycle, so that the Coulomb scattering due to the fixed electric charges in the hafnium silicate nitride film 32b′ is suppressed; therefore, the influence thereof on the electric charges in the channel region 36 is suppressed, and carrier mobility can be enhanced. In addition, since the interface layer 32a is formed in a large film thickness, the electric charges in the channel region 36 are restrained from being trapped by the hafnium silicate nitride film 32b′, and the threshold voltage is prevented from being varied, so that device reliability such as PBTI can be improved. Further, the thickening of the interface layer 32a is attended by a rise in the dielectric constant of the hafnium silicate film 32b, whereby the EOT is maintained, so that the merit of scaling is not spoiled. Therefore, it is possible to favorably cope with processes for CMOS devices of the 45 nm generation and latter generations.

Besides, the second embodiment and the fourth embodiment may be carried out in combination. In this case, for example, the pressure inside the treatment chamber 11 in the oxidizing gas supplying step in the film forming cycle is set higher than the pressure inside the treatment chamber 11 in the raw material gas supplying step. The impurity removing step is conducted every time when the film forming cycle have been repeated a plurality of times.

Incidentally, while an example in which the hafnium silicate film is formed by the ALD process has been described in the first to fourth embodiments above, the present invention is not limited to this example. The film may be a film of other metal silicate such as aluminum silicate, zirconium silicate, etc. or a film of a metal oxide such as hafnium oxide, aluminum oxide, zirconium oxide, etc. Besides, a metal silicate film or metal oxide film in which metals such as Hf, aluminum and zirconium are combined may also be adopted.

In addition, an example in which a sheet fed type ALD apparatus is used has been described in the first to fourth embodiments, the present invention is applicable also to a batch type ALD apparatus in which a plurality of wafers are treated at once.

### EXAMPLES

Examples of the first embodiment above will be described in detail.

### Examples 1 and 2

By the same method as in the first embodiment; a capacitor insulation film 24 composed of a hafnium silicate film shown in FIG. 5 was formed, to obtain a trench capacitor. Example 1 was carried out by setting the pressure inside the treatment chamber 11 (see FIG. 1) in the oxygen-containing gas supplying step (S105) shown in FIG. 3 to 1197 Pa in the same manner as in the first embodiment, whereas Example 2 was carried out by setting the pressure inside the treatment chamber 11 in the oxygen-containing gas supplying step (S105) to 599 Pa.

### Comparative Examples 1 and 2

In addition, Comparative Example 1 was conducted in the same manner as in Example 1, except that the impurity removing step (S105, S106) was omitted. Namely, only the film forming step (S101 to S104) was conducted, whereby the capacitor insulation film 24 composed of a hafnium silicate film was formed, to obtain a trench capacitor. In Comparative Example 2, a trench capacitor including a capacitor insulation film 24 composed of a silicon oxynitride (SiON) was formed.

For the capacitor insulation film 24 composed of the hafnium silicate film in each of Examples 1 and 2 and Comparative Example 1, a graph showing the relationship between the depth from the surface, taken on the axis of abscissas, and the carbon (C) concentration, taken on the axis of ordinates, is shown in FIG. 9. As shown in the graph, it was confirmed that the hafnium silicate film obtained in Example 1 carried out by setting the pressure inside the treatment chamber ii in the oxygen-containing gas supplying step (S105) to 1197 Pa is lowered in peak concentration of impurity C down to 40% based on that of the hafnium silicate film obtained in Comparative Example 1. Besides, it was confirmed that the hafnium silicate film obtained in Example 2 in which the oxygen-containing gas supplying step (S105) was carried out at 599 Pa is lowered in peak concentration of impurity C down to 60% based on that of the hafnium silicate film obtained in Comparative Example 1.

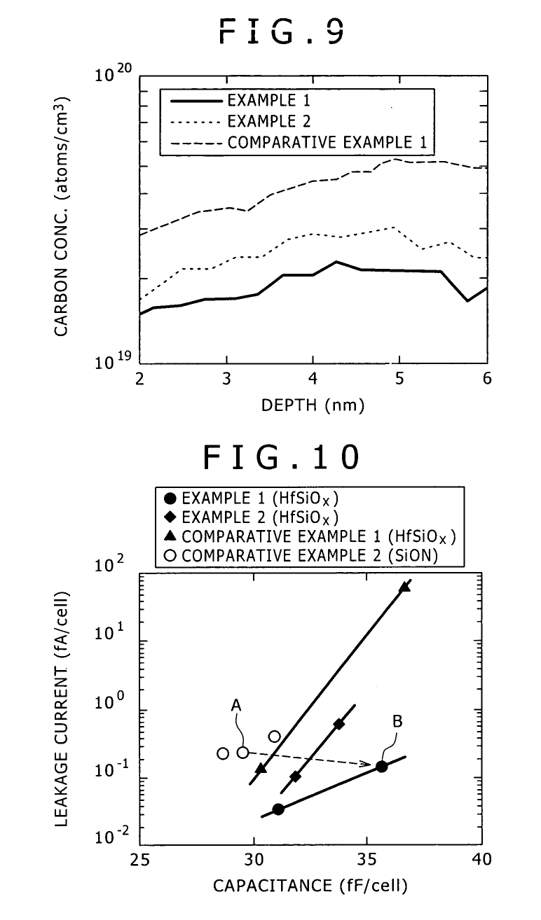

In addition, for the trench capacitors obtained in Examples 1 and 2 and the trench capacitors obtained in Comparative Examples 1 and 2, a graph showing the relationship between leakage current, taken on the axis of ordinates, and capacitance, taken on the axis of abscissas, is shown in FIG. 10. As shown in the graph, it was confirmed that the trench capacitors obtained in Example 1 and Example 2 are remarkably lowered in leakage current, as compared with the trench capacitor obtained in Comparative Example 1. In addition, when the trench capacitor obtained in Comparative Example 2 carried out by using an SiON film as the capacitor insulation film 24 and the trench capacitors obtained in Examples 1 and 2 were compared in capacitance corresponding to the same degree of leakage current, it was confirmed that the capacitance is increased according to the present invention. Particularly, when the trench capacitor obtained in Example 1 and the trench capacitor obtained in Comparative Example 2 were compared at plot A and plot B, at the same degree of leakage current, it was confirmed that the capacitance is increased by no less than 30% according to the present invention.

### Comparative Examples 3 to 6

As Comparative Example 3 relating to Examples 1 and 2, a hafnium silicate film was formed in a thickness of 8 nm by conducting only the film forming cycle (S101 to S104), and thereafter the impurity removing step was conducted by setting the pressure inside the treatment chamber 11 in the oxygen-containing gas supplying step (S105) to 266 Pa, so as to form a capacitor insulation film 24, thereby forming a trench capacitor. In addition, as Comparative Example 4, a trench capacitor was formed in the same manner as in Comparative Example 3, except that the capacitor insulation film 24 was formed by setting the pressure inside the treatment chamber 11 in the oxygen-containing gas supplying step (S105) to 599 Pa.

Further, as Comparative Example 5, a hafnium silicate film was formed in a thickness of 8 nm by conducting only the film forming cycle (S101 to S104), thereafter the substrate 21 was introduced into another chamber, and an annealing treatment was conducted in an O₂ atmosphere at 600° C., so as to form a capacitor insulation film 24, thereby forming a trench capacitor. In addition, as Comparative Example 6, a trench capacitor was produced in the same manner as in Comparative Example 5, except that the annealing treatment was conducted at 700° C. in forming the capacitor insulation film 24.

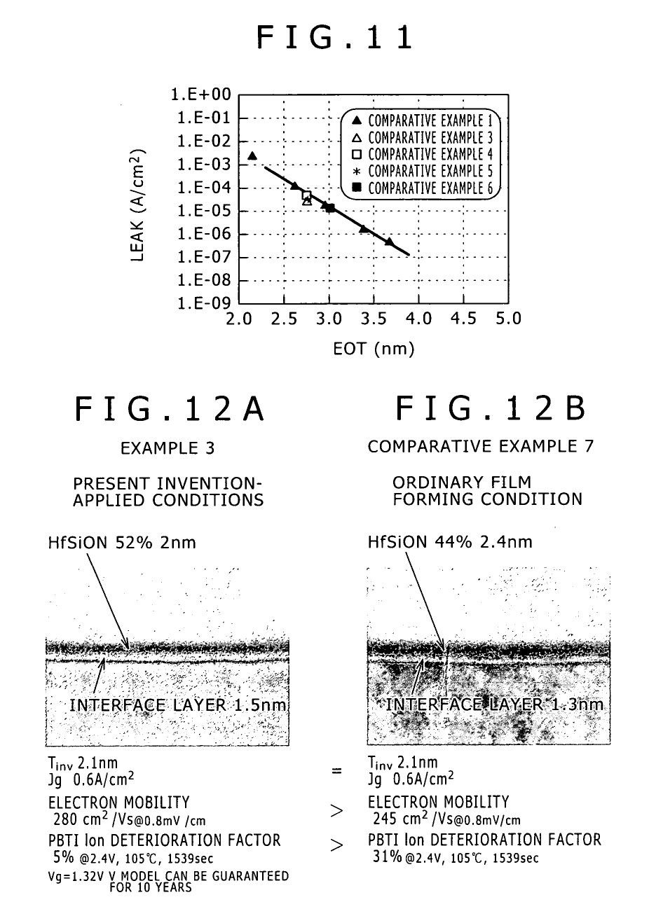

Here, for the trench capacitors obtained in Comparative Examples 3 and 4, EOT of the capacitor insulation film and leakage current were measured. In addition, for the trench capacitor obtained in Comparative Example 1, the leakage current in the case where the EOT of the capacitor insulation film 24 was varied was measured. The results are shown in the graph in FIG. 11. As shown in the graph, it was confirmed for the trench capacitor of Comparative Example 1 that the leakage current increases as the EOT of the capacitor insulation film 24 decreases. Besides, for the trench capacitors of Comparative Examples 3 to 6, leakage current values at the EOT of the capacitor insulation films 24 were comparable to that of the trench capacitor of Comparative Example 1. From this it was confirmed that even if the impurity removing step (S105, S106) or the annealing treatment is conducted after the hafnium silicate film is formed in a thickness of 8 nm, the impurities are not removed and the leakage current is not suppressed.

### Example 3

In the same method as in the second embodiment described referring to FIG. 6, a gate insulation film 32 was formed on a substrate 31. In this case, the film forming cycle (S101 to S104) shown in FIG. 3 was repeated 10 times, then the impurity removing step (S105 and S106) was conducted once, thereafter the film forming cycle (S101 to S104) was repeated 6 times, and the impurity removing step (S105 and S106) was conducted once so as to form a hafnium silicate film 32b, thereby forming a gate insulation film 32 composed of an interface layer 32a and the hafnium silicate film 32b. Subsequently, the gate insulation film 32 was subjected to a plasma nitriding treatment, whereby the hafnium silicate film 32b was converted to a hafnium silicate nitride (HfSiON) film 32b′. Thereafter, an RTA treatment in an N₂ atmosphere at 1000° C. was conducted, and a gate electrode 33 and source/drain electrodes 34 and 35 were formed, to manufacture an nMOSFET with a gate length of 10 μm. As a result, as shown in the sectional TEM photograph in FIG. 12A, a hafnium silicate nitride (HfSiON) film 32b′ was formed in a thickness of 2 nm on the upper side of the substrate 31, through a 1.5 nm thick interface layer 32a therebetween. The composition ration of Hf in the hafnium silicate nitride film was 52%.

### Comparative Example 7

As a comparative example for Example 3, a gate insulation film composed of an interface layer and a hafnium silicate film was formed to manufacture an nMOSFET, in the same manner as in Example 3, except that the impurity removing step was omitted. As a result, as shown in the sectional TEM photograph in FIG. 12B, a hafnium silicate nitride (HfSiON) film was formed in a thickness of 2.4 nm on the upper side of the substrate, with a 1.3 nm thick interface layer therebetween. The composition ratio of Hf in the hafnium silicate nitride film was 44%.

For the nMOSFETs obtained in Example 3 and Comparative Example 7, electron mobility at the time when a unit electric field of 0.8 mV/cm was applied was measured. As a result, under the condition where the electrical film thickness (Tᵢₙᵥ) in a channel inverted state was 2.1 nm and the gate leakage current density (Jg) was kept at 0.6 A/cm², the electron mobility of the nMOSFET of Comparative Example 7 was 245 cm²/Vs, whereas the electron mobility of the nMOSFET of Example 3 was 280 cm²/Vs. Incidentally, the electrical film thickness (Tᵢₙᵥ) is a value obtained by adding the depletion layer film thickness of the gate electrode and the film thickness increment due to the quantum effect to the EOT. As a result, it was confirmed that the nMOSFET of Example 3 is enhanced in electron mobility by no less than 14%, as compared with the nMOSFET of Comparative Example 7.

Besides, for the nMOSFETs obtained in Example 3 and Comparative Example 7, ion deterioration factor upon application of a PBTI stress (2.4 V, 105° C., 1539 sec) was measured. The ion deterioration factor was 31% for the nMOSFET of Comparative Example 7, and was 5% for the nMOSFET of Example 3; thus, the ion deterioration factor was suppressed to ⅙ according to the present invention. As a result, it was confirmed that for the nMOSFET of Example 3, a long-term reliability corresponding to 10 year guarantee with a practical use voltage+10% gate voltage (1.32 V) model is obtained.

It should be understood by those skilled in the art that various modifications, combinations, sub-combinations and alterations may occur depending on design requirements and other factors insofar as they are within the scope of the appended claims or the equivalents thereof.

What is claimed is:

1. A method of forming a thin film by use of an atomic layer deposition process, said process comprising:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere and permitting said oxidizing gas to react with said raw material gas adsorbed on said surface to be treated of said substrate so as to form a layer of oxygen atoms; and
a fourth step of supplying an inert gas into said treatment atmosphere so as to purge said oxidizing gas in said treatment atmosphere,
the film forming cycle of said first to fourth steps being repeated to thereby form said thin film on said surface to be treated,
wherein an impurity removing step including a fifth step of supplying an oxygen-containing gas into said treatment atmosphere so as to oxidize an impurity in said thin film and a sixth step of supplying an inert gas into said treatment atmosphere so as to purge said oxygen-containing gas and said oxidized impurity is conducted between said fourth step and said first step.

2. The method of forming a thin film as set forth in claim 1, wherein
said impurity removing step is conducted once every a plurality of runs of said film forming cycle.

3. The method of forming a thin film as set forth in claim 1, wherein
the pressure of said treatment atmosphere in said fifth step is higher than the pressure of said treatment atmosphere in said third step.

4. The method of forming a thin film as set forth in claim 1, wherein
the temperature of said substrate in said fifth step is higher than the temperature of said substrate in said third step.

5. The method of forming a thin film as set forth in claim 1, wherein
the gas flow rate in said fifth step is higher than the gas flow rate in said third step.

6. The method of forming a thin film as set forth in claim 1, wherein
the treatment time of said fifth step is longer than the treatment time of said third step.

7. The method of forming a thin film as set forth in claim 1, wherein
said oxidizing gas used in said third step is the same as said oxygen-containing gas used in said fifth step.

8. The method of forming a thin film as set forth in claim 7, wherein
the concentration of said oxygen-containing gas in said fifth step is higher than the concentration of said oxidizing gas in said third step.

9. A method of manufacturing a semiconductor device comprising a capacitor having a capacitor insulation film sandwiched between electrodes, wherein
in a step of forming said capacitor insulation film by an atomic layer deposition process,
a film forming cycle including:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere and permitting said oxidizing gas to react with said raw material gas adsorbed on said surface to be treated of said substrate so as to form a layer of oxygen atoms; and
a fourth step of supplying an inert gas into said treatment atmosphere so as to purge said oxidizing gas in said treatment atmosphere,
is repeated, and
an impurity removing step including a fifth step of supplying an oxygen-containing gas into said treatment atmosphere so as to oxidize an impurity in said thin film and a sixth step of supplying an inert gas into said treatment atmosphere so as to purge said oxygen-containing gas and said oxidized impurity is conducted between said fourth step and said first step.

10. A method of manufacturing a semiconductor device comprising a gate electrode provided on the upper side of a substrate, with a gate insulation film therebetween, wherein
in a step of forming said gate insulation film by an atomic layer deposition process,
a film forming cycle including:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere and permitting said oxidizing gas to react with said raw material gas adsorbed on said surface to be treated of said substrate so as to form a layer of oxygen atoms; and
a fourth step of supplying an inert gas into said treatment atmosphere so as to purge said oxidizing gas in said treatment atmosphere,
is repeated, and
an impurity removing step including a fifth step of supplying an oxygen-containing gas into said treatment atmosphere so as to oxidize an impurity in said thin film and a sixth step of supplying an inert gas into said treatment atmosphere so as to purge said oxygen-containing gas and said oxidized impurity is conducted between said fourth step and said first step.

11. A method of forming a thin film by use of an atomic layer deposition process, wherein
said method comprises:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere, under the condition where at least one of the pressure of said treatment atmosphere and the temperature of said substrate is higher than that in said first step, and permitting said oxidizing gas to react with said raw material gas adsorbed on said surface to be treated of said substrate so as to form a layer of oxygen atoms and to oxidize impurities; and
a fourth step of supplying an inert gas into said treatment atmosphere so as to purge said oxidized impurities together with said oxidizing gas in said treatment atmosphere,
the film forming cycle of said first to fourth steps being repeated to thereby form said thin film.

12. A method of manufacturing a semiconductor device comprising a capacitor having a capacitor insulation film sandwiched between electrodes, wherein
a step of forming said capacitor insulation film by an atomic layer deposition process includes:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere, under the condition where at least one of the pressure of said treatment atmosphere and the temperature of said substrate is higher than that in said first step, and permitting said oxidizing gas to react with said raw material gas adsorbed on said surface to be treated of said substrate so as to form a layer of oxygen atoms and to oxidize impurities; and
a fourth step of supplying an inert gas into said treatment atmosphere so as to purge said oxidized impurities together with said oxidizing gas in said treatment atmosphere,
the film forming cycle of said first to fourth steps being repeated to thereby form said capacitor insulation film.

13. A method of manufacturing a semiconductor device comprising a gate electrode provided on the upper side of a substrate, with a gate insulation film therebetween, wherein
a step of forming said gate insulation film by use of an atomic layer deposition process includes:
a first step of supplying a raw material gas containing at least either of metallic atoms and silicon atoms into a treatment atmosphere and adsorbing a raw material gas component onto a surface to be treated of a substrate so as thereby to form a layer containing at least either of said metallic atoms and said silicon atoms;
a second step of supplying an inert gas into said treatment atmosphere so as to purge said raw material gas in said treatment atmosphere;
a third step of supplying an oxidizing gas into said treatment atmosphere, under the condition where at least one of the pressure of said treatment atmosphere and the temperature of said substrate is higher than that in said first step, and permitting said oxidizing gas to react with said raw material gas adsorbed on said surface to be treated of said substrate so as to form a layer of oxygen atoms and to oxidize impurities; and
a fourth step of supplying an inert gas into said treatment atmosphere so as to purge said oxidized impurities together with said oxidizing gas in said treatment atmosphere,
the film forming cycle of said first to fourth steps being repeated to thereby form said gate insulation film.
